(19) United States
(12) Patent Application Publication
(10) Pub. No.: US 2026/0114228 A1
(43) Pub. Date: Apr. 23, 2026

(54) TRANSFER UNIT AND SUPPORT UNIT

(71) Applicant: SEMES CO., LTD., Cheonan-si (KR)

(72) Inventors: Hyun Jun KIM, Pyeongtaek-si (KR); Jun Ho YOU, Cheonan-si (KR)

(73) Assignee: SEMES CO., LTD., Cheonan-si (KR)

(21) Appl. No.: 19/364,220

(22) Filed: Oct. 21, 2025

(30) Foreign Application Priority Data
Oct. 23, 2024 (KR) 10-2024-0145883

(51) Int. Cl. H01L 21/68; H01L 21/687

(52) U.S. Cl. CPC H10P 72/53; H10P 72/7602

(57) ABSTRACT

Provided is a transfer unit for transferring a substrate. The transfer unit includes: a hand on which a substrate is placed; and a detector for detecting the degree to which the substrate placed on the hand is out of a correct position of the substrate on the hand. The detector includes: a light emitting sensor located on one side between an upper side and a lower side of the substrate placed at the correct position on the hand to emit light; and a light receiving sensor located on the other side between the upper side and the lower side of the substrate placed at the correct position on the hand to receive the light emitted by the light emitting sensor. The light emitting sensor is installed to emit light obliquely to the substrate in a direction toward an outside of a radial direction of the substrate placed at the correct position on the hand.

### CROSS-REFERENCE TO RELATED APPLICATION

This application claims priority to and the benefit of Korean Patent Application No. 10-2024-0145883 filed in the Korean Intellectual Property Office on Oct. 23, 2024, the entire contents of which are incorporated herein by reference.

### TECHNICAL FIELD

The present invention relates to a transfer unit that transfers a substrate and a support unit that supports a substrate, and more specifically, to a transfer unit and a support unit that are capable of detecting a position of a substrate.

### BACKGROUND ART

To manufacture a semiconductor device or liquid crystal display, various processes, such as photolithography, etching, ashing, ion implantation, thin film deposition, and cleaning, are performed on a substrate. Among them, the photolithography process includes an application process of applying a photoresist on the substrate, an exposure process of transferring a pattern to the photoresist on the substrate, and a development process of removing the selected region from the exposed substrate. The devices provided to perform these processes include a transfer unit that transfers the substrate between chambers performing different processes.

Depending on the type of process, it is important for the transfer unit to accurately transfer the substrate to the position set in the chamber when transferring the substrate into the chamber. For example, when the substrate is not accurately placed at the specified position in the chamber that performs an edge bead removal process of removing the photoresist from the edge region on the substrate after applying the photoresist to the substrate or an edge exposure process of exposing the edge region on the substrate, the edge bead removal region or edge exposure region in the edge region of the substrate are different from each other.

In general, the transfer unit detects whether the substrate is placed at the correct position on the hand while the substrate is supported on the hand, corrects the transfer position where the transfer unit transfers the substrate to the chamber according to the detection result, or transfers the substrate to the chamber after placing the substrate at the correct position on the hand. In order to detect the position of the substrate on the hand, a plurality of detectors for detecting the position of the end portion of the substrate is provided in the transfer unit. Each detector includes a light emitting sensor and a light receiving sensor. The light emitting sensor emits light toward a light irradiation region including an end portion of the substrate, and the light receiving sensor receives light emitted by the light emitting sensor. Further, the detector detects the position of the end portion of the substrate based on the amount of light received by the light receiving sensor, and determines the position of the substrate on the hand based on the position of the end portion of the substrate detected by the plurality of detectors.

FIG. 1 is a diagram schematically illustrating a traveling direction of light in a detector according to a general transfer unit.

Generally, a light emitting sensor 1110 and a light receiving sensor 1120 are disposed to face each other with a substrate W placed on a hand (not illustrated) interposed therebetween. A light emitting surface 1112 of the light receiving sensor 1110, a light receiving surface 1122 of the light receiving sensor 1120, and the substrate W are provided in parallel with each other.

In general, an end portion A of the substrate W has a rounded shape. Accordingly, in the above arrangement, among the lights emitted from the light emitting sensor 1110, the light hitting the end portion A of the substrate W is diffusely reflected. By the diffuse reflection, the light receiving sensor 1120 receives a greater amount of light than the amount of light received when diffuse reflection is not performed. Accordingly, it is difficult to accurately determine the position of the end portion A of the substrate W.

Also, the degree of diffuse reflection differs according to the type of film formed at the end portion A of the substrate W. Accordingly, even for the substrates W positioned at the same position, the positions of the end portions A of the substrates W may be detected differently according to the type of film formed at the end portion A of the substrate W.

In particular, vibration occurs for various reasons during the process, which causes shaking to be transmitted to the sensor, preventing accurate light emission to the end portion A of the substrate W, increasing the influence of diffuse reflection.

### SUMMARY OF THE INVENTION

The present invention has been made in an effort to provide a transfer unit and a support unit capable of improving detection accuracy when a position of an end portion of a substrate is detected by using a light emitting sensor and a light receiving sensor.

The present invention has also been made in an effort to provide a transfer unit and a support unit capable of accurately detecting a position of a substrate on a hand when the substrate is placed on the hand of the transfer unit.

The objectives of the present disclosure are not limited thereto and other objectives not stated herein may be clearly understood by those skilled in the art from the following description.

An exemplary embodiment of the present disclosure, a transfer unit for transferring a substrate, the transfer unit comprising: a hand on which a substrate is placed; and a detector for detecting the degree to which the substrate placed on the hand is out of a correct position of the substrate on the hand, wherein the detector includes: a light emitting sensor located on one side between an upper side and a lower side of the substrate placed at the correct position on the hand to emit light; and a light receiving sensor located on the other side between the upper side and the lower side of the substrate placed at the correct position on the hand to receive the light emitted by the light emitting sensor, and the light emitting sensor may be installed to emit light obliquely to the substrate in a direction toward an outside of a radial direction of the substrate placed at the correct position on the hand.

An exemplary embodiment of the present disclosure, a support unit for supporting a substrate, the support unit comprising: a support for supporting a substrate; and a detector for detecting the degree to which the substrate placed on the support is out of a correct position of the substrate on the support, wherein the detector includes: a light emitting sensor located on one side between an upper side and a lower side of the substrate placed at the correct position on the support to emit light; and a light receiving sensor located on the other side between the upper side and the lower side of the substrate placed at the correct position on the support to receive the light emitted by the light emitting sensor, and the light emitting sensor may be installed to emit light obliquely to the substrate in a direction toward an outside of a radial direction of the substrate placed at the correct position on the support.

An exemplary embodiment of the present disclosure, a transfer unit for transferring a substrate, the transfer unit comprising: a base plate; a hand which is provided to be movable forward and backward with respect to the base plate, and on which the substrate is placed; and a plurality of detectors for detecting the degree to which the substrate placed on the hand is out of a correct position of the substrate on the hand when the hand is located at a retracted position with respect to the base plate, wherein the plurality of detectors is installed on the base plate to detect different regions of the substrate placed on the hand, each of the detectors includes: a light emitting sensor located on one side of an upper side and a lower side of the substrate placed at the correct position on the hand to emit light; and a light receiving sensor located on the other side between the upper side and the lower side of the substrate placed at the correct position on the hand to receive the light emitted by the light emitting sensor, and the light emitting sensor may be installed to emit light obliquely to the substrate in a direction toward an outside of a radial direction of the substrate placed at the correct position on the hand.

According to the exemplary embodiment of the present invention, it is possible to improve detection accuracy when a position of an end portion of a substrate is detected by using a light emitting sensor and a light receiving sensor.

According to the exemplary embodiment of the present invention, it is possible to accurately detect a position of a substrate on a hand when the substrate is placed on the hand of the transfer unit.

Effects of the present disclosure are not limited to those described above and effects not stated above will be clearly understood to those skilled in the art from the specification and the accompanying drawings.

### BRIEF DESCRIPTION OF THE DRAWINGS

The various features and advantages of the non-limiting exemplary embodiment of the present specification may become more apparent by reviewing the detailed description together with the accompanying drawings. The accompanying drawings are provided for illustrative purposes only and should not be construed as limiting the scope of claims. The accompanying drawings are not considered to be drawn to scale unless explicitly stated. For clarity, the various dimensions of the drawings may have been exaggerated.

FIG. 1 is a diagram schematically illustrating a traveling direction of light in a detector according to a general transfer unit.

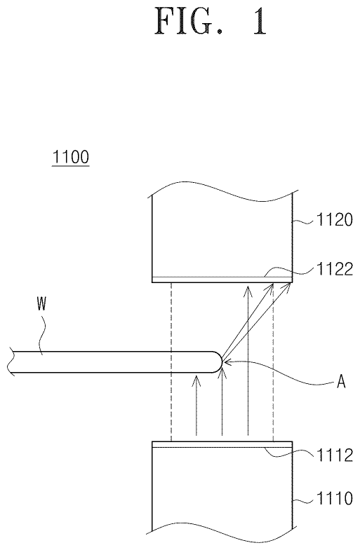

FIG. 2 is a perspective view schematically illustrating a substrate processing apparatus according to an exemplary embodiment of the present invention.

FIG. 3 is a cross-sectional view of the substrate processing apparatus illustrating an applying block or a developing block of FIG. 2.

FIG. 4 is a top plan view of the substrate processing apparatus of FIG. 2.

FIG. 5 is a top plan view schematically illustrating one example of a heat processing chamber of FIG. 4.

FIG. 6 is a front view of the heat processing chamber of FIG. 5.

FIG. 7 is a diagram schematically illustrating an example of a transfer unit.

FIG. 8 is a diagram schematically illustrating an example of a hand of the transfer unit of FIG. 7.

FIG. 9 is a diagram schematically illustrating an exemplary embodiment of a detector of the transfer unit of FIG. 7.

FIGS. 10 and 11 are diagrams schematically illustrating methods of setting an angle of the detector of FIG. 9, respectively.

FIG. 12 is a diagram schematically illustrating light emitted by the detector of the transfer unit of FIG. 9.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

An expression, “and/or” includes each of the mentioned items and all of the combinations including one or more of the items. Further, in the present specification, “connected” means not only when member A and member B are directly connected, but also when member A and member B are indirectly connected by interposing member C between member A and member B.

Embodiments of the present disclosure may be modified in various ways and the scope of the present disclosure should not be construed as being limited to the embodiments to be described below. Embodiments are provided to more completely explain the present disclosure to those skilled in the art. Accordingly, the shapes of the components shown in the figures are exaggerated to enhance clearer description.

The facility in the present exemplary embodiment is described as being used to perform photolithography processes on substrates, such as semiconductor wafers or flat displays panels, but this is for convenience of description, and the present invention may also be used in other devices including robots that transfer substrates to process substrates.

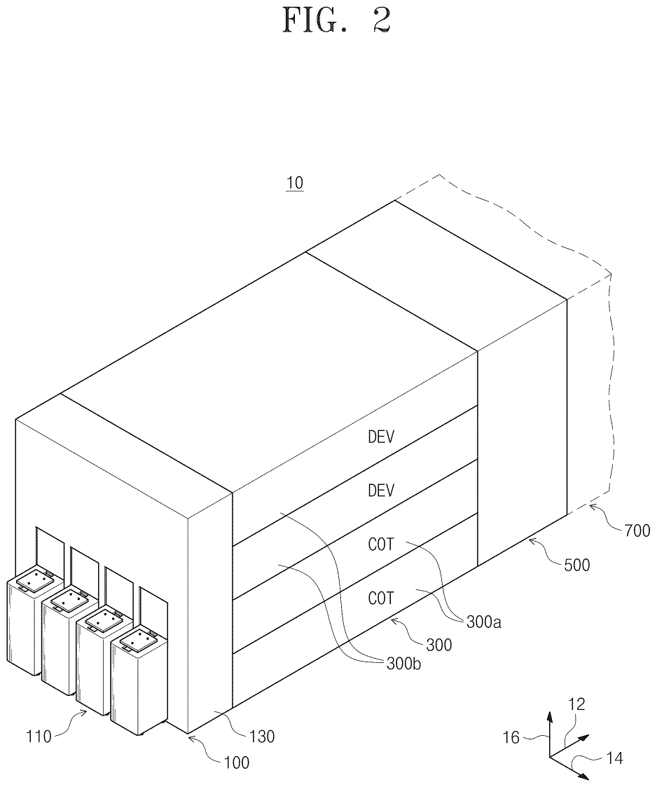

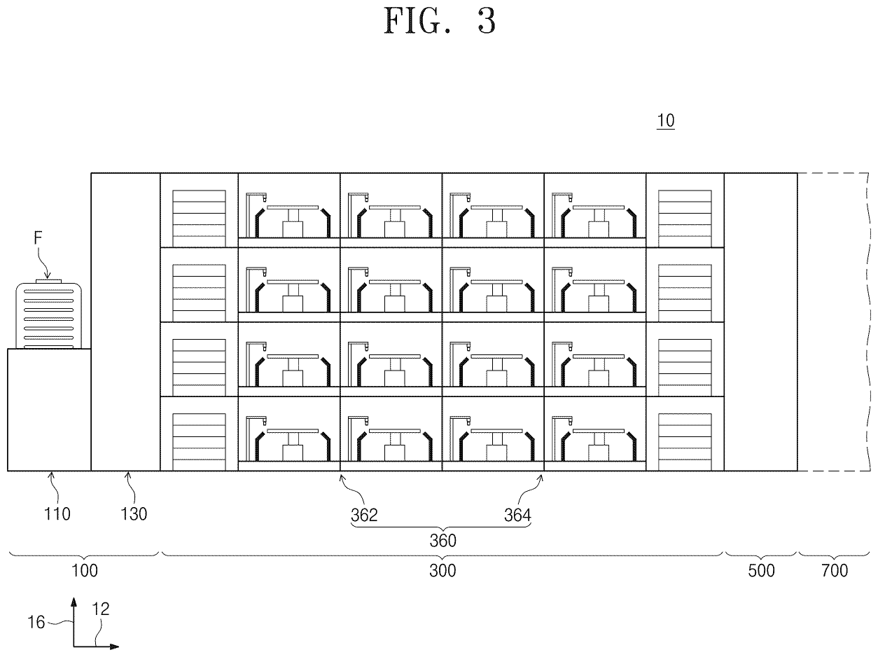

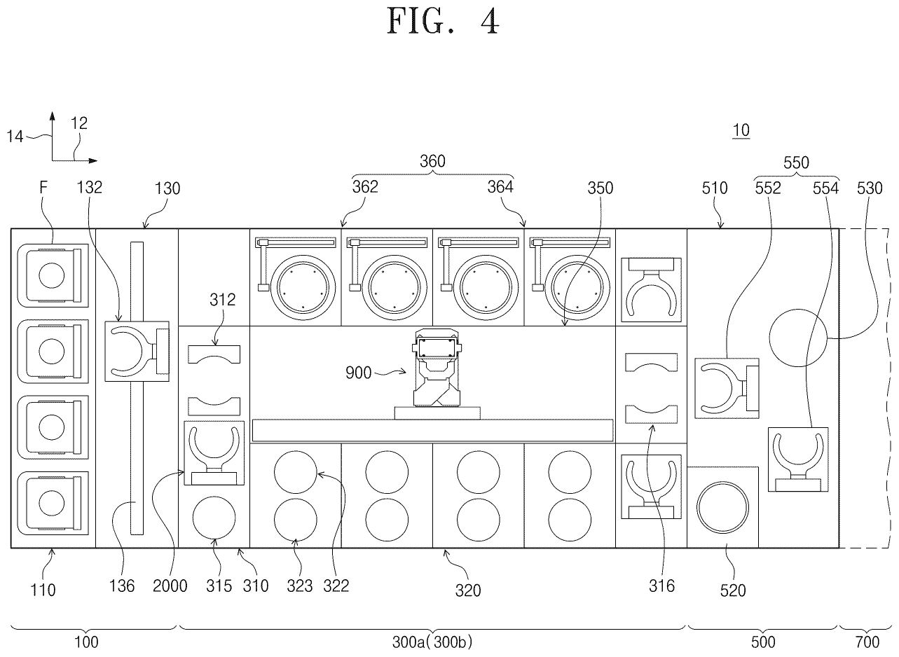

FIG. 2 is a perspective view schematically illustrating a substrate processing apparatus according to an exemplary embodiment of the present invention, FIG. 3 is a cross-sectional view of the substrate processing apparatus illustrating an applying block or a developing block of FIG. 2, and FIG. 4 is a top plan view of the substrate processing apparatus of FIG. 2.

Referring to FIGS. 2 to 4, a substrate processing apparatus 10 according to an exemplary embodiment of the present invention includes an index module 100, a processing module 300, and an interface module 500.

According to the exemplary embodiment, the index module 100, the processing module 300, and the interface module 500 are sequentially arranged in a line. Hereinafter, a direction in which the index module 100, the processing module 300, and the interface module 500 are arranged is referred to as a first direction 12, a direction perpendicular to the first direction 12 when viewed from above is referred to as a second direction 14, and a direction perpendicular to both the first direction 12 and the second direction 14 is defined as a third direction 16.

The index module 100 transfers a substrate W from a container F in which the substrate W is accommodated to the processing module 300, and makes the substrate W, which has been completely processed in the processing module 20, be accommodated in the container F. A longitudinal direction of the index module 100 is provided in the second direction 14. The index module 100 includes a load port 110 and an index frame 130. Based on the index frame 130, the load port 110 is located at a side opposite to the processing module 300. The containers F in which the substrates W are accommodated are placed on the load ports 110. A plurality of load ports 110 may be provided, and the plurality of load ports 110 may be disposed in the second direction 14.

As the container F, an airtight container, such as a Front Open Unified Pod (FOUP), may be used. The container F may be placed on the load port 110 by a transfer means (not illustrated), such as an overhead transfer, an overhead conveyor, or an automatic guided vehicle, or an operator.

An index robot 132 is provided to the index frame 130. A guide rail 136 of which a longitudinal direction is the second direction 92 is provided within the index frame 130, and the index robot 132 may be provided to be movable on the guide rail 136. The index robot 132 includes a hand on which the substrate W is placed, and the hand may be provided to be movable forward and backward, rotatable about the third direction 16, and movable along the third direction 16.

The processing module 300 may perform an application process and a development process on the substrate W. The processing module 300 may perform a substrate processing process by receiving the substrate W accommodated in the container F. The processing module 300 includes an applying block 300a, a developing block 300b, and a front buffer chamber 310.

The applying block 300a performs an application process on the substrate W, and the developing block 300b performs a development process on the substrate W. A plurality of applying blocks 300a is provided, and they are provided to be stacked on each other. A plurality of developing blocks 300b is provided, and they are provided to be stacked on each other. According to the exemplary embodiment of FIG. 2, two applying blocks 300a and two developing blocks 300b are provided. The applying blocks 300a may be disposed under the developing blocks 300b. According to an example, the two applying blocks 300a perform the same process and may be provided in the same structure. Further, the two developing blocks 300b perform the same process and may be provided in the same structure.

Referring to FIG. 4, the applying block 300a includes a heat processing chamber 320, a transfer chamber 350, and a liquid processing chamber 360.

The heat processing chamber 320 performs a heat processing process on the substrate W. The heat processing process may include a cooling process and a heating process. The liquid processing chamber 360 forms a liquid film by supplying a liquid onto the substrate W. The liquid film may be a photoresist film or an antireflection film. The transfer chamber 350 transfers the substrate W between the heat processing chamber 320 and the liquid processing chamber 360 within the applying block 300a.

The transfer chamber 350 may be provided so that a longitudinal direction is parallel to the first direction 12. A transfer robot 900 is provided to the transfer chamber 350. The transfer robot 900 transfers the substrate between the heat processing chamber 320, the liquid processing chamber 360, and the buffer chambers 312 and 316. According to an example, the transfer robot 900 includes a hand on which the substrate W is placed, and the hand may be provided to be movable forward and backward, rotatable about the third direction 16, and movable along the third direction 16.

The front buffer chamber 310 may include a buffer transfer unit 2000, a plurality of buffer modules 312, and an adhesion baking module 315.

Some of the buffer modules 312 may include a cool plate where a substrate waits before being introduced into the applying block 300a after an adhesion baking processing.

An adhesion baking module 315 for hydrophobizing the surface of the substrate with hydrophobic gas before the applying process may be positioned at one side of the buffer transfer unit 2000. Herein, the hydrophobic gas may be hexamethyldisilane (HMDS).

The buffer transfer unit 2000 is disposed on one side of the buffer module 312. The buffer transfer unit 1000 may include a buffer loading robot that transfers a substrate before process processing to an applying module for the applying process, and a buffer unloading robot that moves the substrate W to the buffer module 312 located at a third or fourth stage so that the index robot 132 is capable of withdrawing the substrate after the process processing.

Referring back to FIGS. 2 to 4, a plurality of heat processing chambers 320 is provided. The heat processing chambers 320 are disposed along the first direction 12. The heat processing chambers 320 are located on one side of the transfer chamber 350.

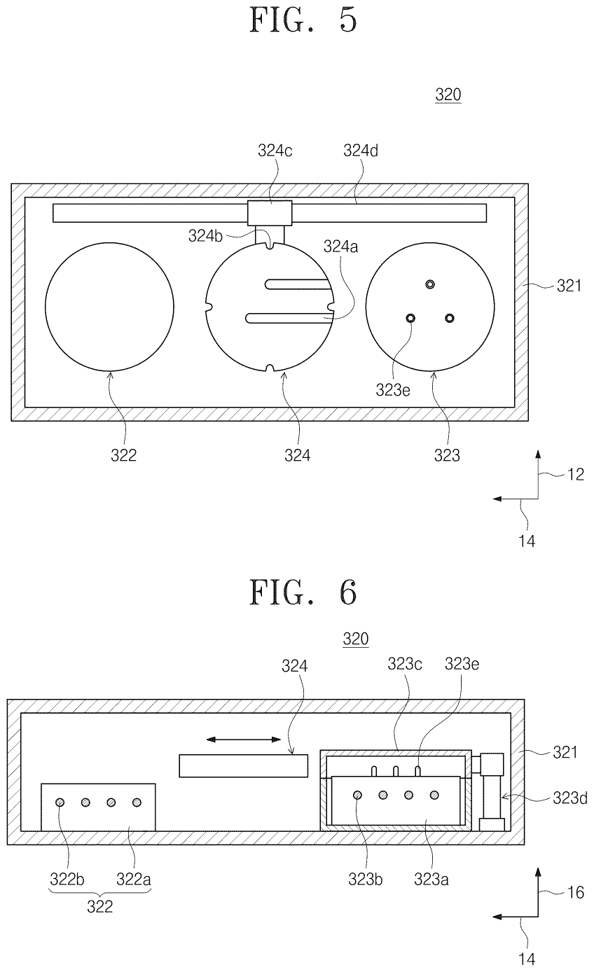

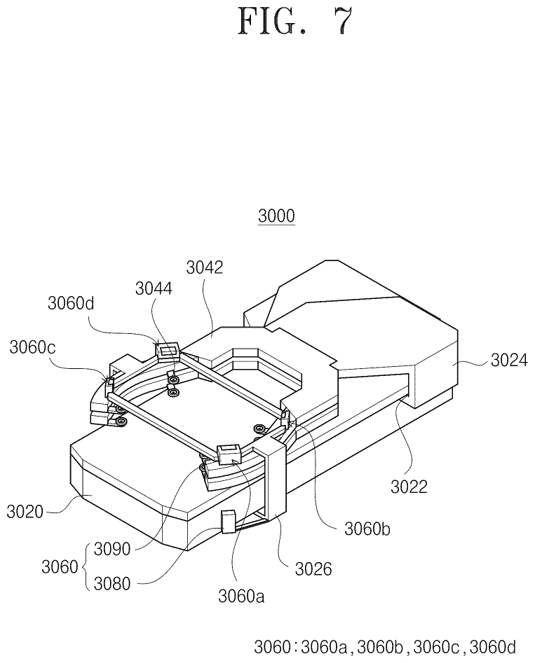

FIG. 5 is a top plan view schematically illustrating one example of a heat processing chamber of FIG. 4, and FIG. 6 is a front view of the heat processing chamber of FIG. 5.

Referring to FIGS. 5 and 6, the heat processing chamber 320 includes a housing 321, a cooling member 322, a heating unit 323, and a transfer plate 324.

The housing 321 is provided in a generally rectangular parallelepiped shape. An entrance opening (not illustrated) through which the substrate W enters and exits is formed on a sidewall of the housing 321. The entrance opening may remain open. A door (not illustrated) may be provided to selectively open and close the entrance opening. The cooling member 322, the heating unit 323, and the transfer plate 324 are provided within the housing 321. The cooling member 322 and the heating unit 323 are arranged along the second direction 14. According to an example, the cooling unit 322 may be positioned closer to the transfer chamber 350 than the heating unit 323.

The cooling unit 322 has a cooling plate 322a. When viewed from above, the cooling plate 322a may have a substantially circular shape. A cooling member 322b is provided to the cooling plate 322a. According to an example, the cooling member 322b is formed inside the cooling plate 322a and may be provided as a flow path through which a cooling fluid flows.

The heating unit 323 includes a heating plate 323a, a cover 323c, and a heater 323b. When viewed from above, the heating plate 323a has a generally circular shape. The heating plate 323a has a larger diameter than the substrate W. The heater 323b is installed on the heating plate 323a. The heater 323b may be provided as a heating resistor to which a current is applied. The heating plate 323a is provided with lift pins 323e that may be driven in the vertical direction along the third direction 16. The lift pin 323e receives the substrate W from a transfer means outside the heating unit 323 and puts the received substrate W down on the heating plate 323a, or lifts the substrate W from the heating plate 323a and hands over the substrate W to the transfer means outside the heating unit 323. According to an example, three lift pins 323e may be provided.

The cover 323c has an internal space with an open lower portion. The cover 323c is positioned above the heating plate 323a and is moved in the vertical direction by a driver 3236d. A space formed by the cover 323c and the heating plate 323a by moving the cover 323c is provided as a heating space for heating the substrate W.

The transfer plate 324 is generally provided with a disk shape and has a diameter corresponding to that of the substrate W. A notch 324b is formed at an edge of the transfer plate 324. The notch 324b may have a shape corresponding to that of a protrusion 3044 formed in the hand 354 of the transfer robot 3040 described below. Also, the notch 324b is provided by the number corresponding to the number of protrusions 3044 formed in the hand 3040, and is formed at a position corresponding to that of the protrusion 3044. When the vertical positions of the hand 354 and the transfer plate 324 are changed at a position where the hand 354 and the transfer plate 324 are vertically aligned, the substrate W is transferred between the hand 354 and the transfer plate 324. The transfer plate 324 may be mounted on the guide rail 324d and may be moved between a first region 3212 and a second region 3214 along the guide rail 324d by the driver 324c. A plurality of slit-shaped guide grooves 324a is provided in the transfer plate 324. The guide groove 324a extends from the distal end of the transfer plate 324 to the inside of the transfer plate 324. The guide groove 324a is provided so that a longitudinal direction thereof is the second direction 14, and the guide grooves 324a are spaced apart from each other along the first direction 12. The guide groove 324a prevents the transfer plate 324 and the lift pin 323e from interfering with each other when the substrate W is taken over between the transfer plate 324 and the heating unit 323.

Cooling of the substrate W is performed in a state in which the transfer plate 324 on which the substrate W is placed is in contact with the cooling plate 322a. The transfer plate 324 is made of a material having high thermal conductivity so that heat transfer between the cooling plate 322a and the substrate W is well performed. According to an example, the transfer plate 324 may be made of a metal material.

Referring back to FIGS. 2 to 4, a plurality of heat processing chambers 360 is provided. Some of the liquid processing chambers 360 may be provided to be stacked on each other. The liquid processing chambers 360 are disposed on one side of the transfer chamber 350. The liquid processing chambers 360 are arranged side by side along the first direction 12. Another part of the liquid processing chambers 360 is provided at a position adjacent to the index module 100. Hereinafter, the liquid processing chamber 360 positioned adjacent to the index module 100 is referred to as a front liquid processing chamber 362. Another part of the liquid processing chambers 360 are provided at positions adjacent to the interface module 500. Hereinafter, the liquid processing chamber 360 positioned adjacent to the interface module 500 is referred to as a rear liquid processing chamber 364.

The front liquid processing chamber 362 applies a first liquid on the substrate W, and the rear liquid processing chamber 364 applies a second liquid on the substrate W. The first liquid and the second liquid may be different types of liquids. According to the example, the first liquid is an antireflection film, and the second liquid is a photoresist. The photoresist may be applied on the substrate W to which the antireflection film is applied. Optionally, the first liquid may be a photoresist, and the second liquid may be an antireflection film. In this case, the antireflection film may be applied on the substrate W to which the photoresist is applied. Optionally, the first liquid and the second liquid are the same type of liquid, and all of them may be photoresist.

The developing block 300b has the same structure as the applying block 300a, and the liquid processing chamber provided to the developing block 300b supplies a developer onto the substrate.

The interface module 500 connects the processing module 300 to an external exposure device 700. The interface module 500 includes an interface frame 510, an additional process chamber 520, an interface buffer 530, and an interface robot 550.

A fan filter unit that forms descending airflow therein may be provided at an upper end of the interface frame 510. The additional process chamber 520, the interface buffer 530, and the interface robot 550 are disposed within the interface frame 510. The additional process chamber 520 may perform a predetermined additional process before the substrate W on which the process has been completed in the applying block 300a is loaded into the exposure module 700. Optionally, the additional process chamber 520 may perform a predetermined additional process before the substrate W on which the process has been completed in the exposure device 700 is loaded into the developing block 300b. According to an example, the additional process may be an edge exposure process for exposing an edge region of the substrate W, an upper surface cleaning process for cleaning the upper surface of the substrate W, or a lower surface cleaning process for cleaning the lower surface of the substrate W. A plurality of additional process chambers 520 may be provided, and they may be provided to be stacked on each other. All of the additional process chambers 520 may be provided to perform the same process. Optionally, some of the additional process chambers 520 may be provided to perform different processes.

The interface buffer 530 provides a space in which the substrate W transferred between the applying block 300a, the additional process chamber 520, the exposure device 700, and the developing block 300b temporarily stays during transfer. A plurality of interface buffers 530 may be provided, and a plurality of interface buffers 530 may be provided to be stacked on each other.

According to an example, the additional process chamber 520 may be disposed on one side based on an extension line of the transfer chamber 350 in the longitudinal direction and the interface buffer 530 may be disposed on the other side.

The interface robot 550 transfers the substrate W between the applying block 300a, the additional process chamber 520, the exposure device 700, and the developing block 300b. The interface robot 550 may have a transfer hand that transfers the substrate W. The interface robot 550 may be provided as one or a plurality of robots. According to an example, the interface robot 550 includes a first robot 552 and a second robot 554. The first robot 552 may be provided to transfer the substrate W between the applying block 300a, the additional process chamber 520, and the interface buffer 530, the second robot 554 may be provided to transfer the substrate W between the interface buffer 530 and the exposure device 700, and the second robot 554 may be provided to transfer the substrate W between the interface buffer 530 and the developing block 300b.

Each of the first robot 552 and the second robot 554 includes a transfer hand on which the substrate W is placed, and the hand may be provided to be movable forward and backward, rotatable based on an axis parallel to the third direction 16, and movable along the third direction 16.

Hereinafter, the transfer unit for transferring a substrate will be described in detail.

Hereinafter, the present invention will be described based on the case where the transfer unit is the transfer robot provided in the transfer chamber as an example. However, unlike this, the transfer unit may be an index robot or an interface robot. Optionally, the transfer unit may be a buffer transfer robot.

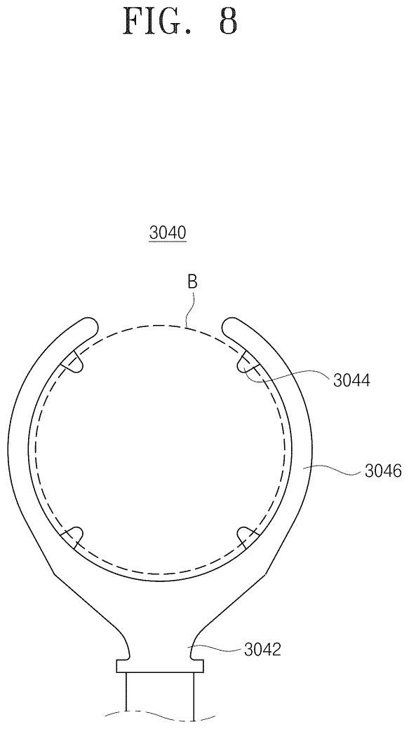

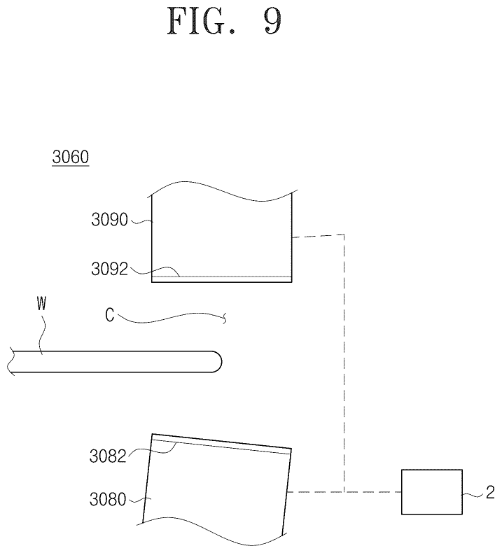

FIG. 7 is a diagram schematically illustrating an example of the transfer unit, and FIG. 8 is a diagram schematically illustrating an example of the hand of the transfer unit of FIG. 7.

Referring to FIG. 7, a transfer unit 3000 includes a base plate 3020, a hand 3040, and a detector 3060. The base plate 3020 is generally provided in a rectangular parallelepiped cylindrical shape. The base plate 3020 is provided to be movable in the first direction 12 and the third direction 16 by a driving means (not illustrated).

The hand 3040 is installed on the base plate 3020 to be movable forward and backward with respect to the base plate 3020.

A hand driver (not illustrated) for moving the hand 3040 forward and backward is installed inside the base plate 3020. The hand driver moves the hand 3040 between a forward position and a retracted position on the base plate 3020.

A guide groove 3022 is formed on a side surface of the base plate 3020. A hand support 3024 is inserted into the guide groove 3022. The guide groove 3022 is formed in a slit shape along a longitudinal direction of the base plate 3020.

The hand support 3024 is disposed through the guide groove 3022. The hand support 3024 may be provided in a bar shape. One end of the hand support 3024 is coupled to a driver (not illustrated), and the other end of the hand support 3024 is coupled to the hand 3040.

FIG. 8 is a diagram schematically illustrating an example of the hand of the transfer unit of FIG. 7.

Referring to FIG. 8, the hand 3040 supports a substrate. The hand 3040 includes a hand body 3042 and a supporting protrusion 3044. The hand body 3042 has an annular ring shape in which a portion of a circumference is bent. The supporting protrusion 3044 is provided on the hand body 3042. The supporting protrusion 3044 extends from an inner surface of the hand body 3042 toward a center of the hand body 3042. A plurality of supporting protrusions 3044 is provided. For example, four supporting protrusions 3044 may be provided at equal intervals. The substrate W is supported by the supporting protrusion 3044 in the hand 3040.

Referring back to FIG. 7, a plurality of hands 3040 is provided. For example, the hand 3040 may be provided by combining two hands 3040. In this case, the two hands 3040 are disposed to be spaced apart from each other in the vertical direction. Each hand 3040 is individually moved forward and retracted by a driver (not illustrated). For example, when one hand 3040 is fixed to the retracted position, the other hand 3040 may be moved forward and backward.

The detector 3060 detects the position of the substrate W placed on the hand 3040. A plurality of detectors 3060 is provided. In one exemplary embodiment, four detectors 3060 may be provided. The detector 3060 is installed on the base plate 3020. When a direction in which the substrate W moves forward and backward with respect to the base plate 3020 is considered as a reference line, the two detectors 3060a and 3060b may be installed on one side of the reference line, and the remaining two detectors 3060c and 3060d may be located on the other side of the reference line. The detector 3060 includes a light emitting sensor 3080, a light receiving sensor 3090, and a holder 3030. The holder 3030 has a side wall 3032 and a lower wall 3034. The holder 3030 is provided on a side surface of the base plate 3020. The side wall 3032 and the lower wall 3034 of the holder 3030 are perpendicular to each other. The light emitting sensor 3080 is disposed in a structure surrounded by the holder 3030. The light emitting sensor 3080 is supported by the holder 3030.

A bracket 3026 is installed on the base plate 3020. The bracket 3026 is installed on a side surface of the base plate 3020. The bracket 3026 is provided to surround the upper portion of the hand 3040 and the outer side of the hand body 3042. A light receiving sensor 3090 is fixed and coupled to the bracket 3026. For example, the light receiving sensor 3090 is installed on the bracket 3026.

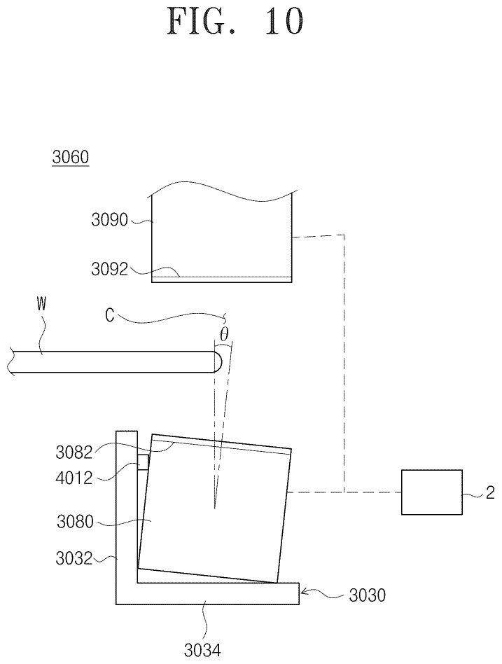

FIG. 9 is a diagram schematically illustrating an exemplary embodiment of the detector of the transfer unit of FIG. 7.

Referring to FIG. 9, the holder 3030 supports the light emitting sensor 3080. The light emitting sensor 3080 and the light receiving sensor 3090 are installed at positions to detect the position of the end portion of the substrate W placed on the hand 3040 when the hand 3040 is in the retracted position. The light emitting sensor 3080 and the light receiving sensor 3090 are installed to face each other with the hand 3040 interposed therebetween.

The light emitting sensor 3080 has a light emitting surface 3082 for emitting light. The light emitting surface 3082 emits light to a light irradiation region C including the end portion of the substrate W. The light emitting surface 3082 has a predetermined width in the radial direction of the substrate W.

The light receiving sensor 3090 has a light receiving surface 3090 that receives light emitted from the light emitting sensor 3080. The light receiving surface 3092 has a certain width in the radial direction of the substrate W. When viewed from above, light emitted from the light irradiation surface 3082 to the region covered by the substrate W is not received from the light receiving surface 3092. The light emitted from the light emitting surface 3082 to the region that is not covered by the substrate W is received in the light receiving surface 3092. The position of the end portion of the substrate W may be detected based on the amount of light received by the light receiving sensor 3090.

The holder 3030 is provided to surround the bottom surface and one side surface of the light emitting sensor 3080. For example, the holder 3030 has a sidewall 3032 and a lower wall 3034, and the sidewall 3032 and the lower wall 3034 are provided in a frame shape in which the sidewall 3032 and the lower wall 3034 are perpendicular to each other. The lower wall 3034 of the holder 3030 extends from the bracket 3026 to the lower end of the side surface of the base plate 3020. The holder 4010 supports and fixes the light emitting sensor 3080 to minimize an error that may occur when the light emitting sensor 3080 is shaken due to vibration.

The light emitting sensor 3080 is disposed to obliquely emit light to the substrate W in a direction in which the light emitting surface 3082 thereof faces outward in the radial direction of the substrate W. The light receiving sensor 3090 is disposed such that the light receiving surface 3092 is parallel to a substrate W. Accordingly, the light emitting surface 3082 of the light emitting sensor 3080 is provided to be inclined with respect to the light receiving surface 3092 of the light receiving sensor 3090.

Light is emitted to an imaginary straight line perpendicular to the substrate W at an inclination of a predetermined angle θ. The light emitting sensor 3080 is provided so that the light has an angle θ in the range of 1° to 6° with respect to a virtual straight line perpendicular to the substrate W. In the exemplary embodiment, the irradiation angle θ of light may be an angle within a range of 2° to 5°. For example, the irradiation angle θ of light may be 3°.

The specific method of setting the angle θ of the detector 3060 of the present invention includes the following two methods.

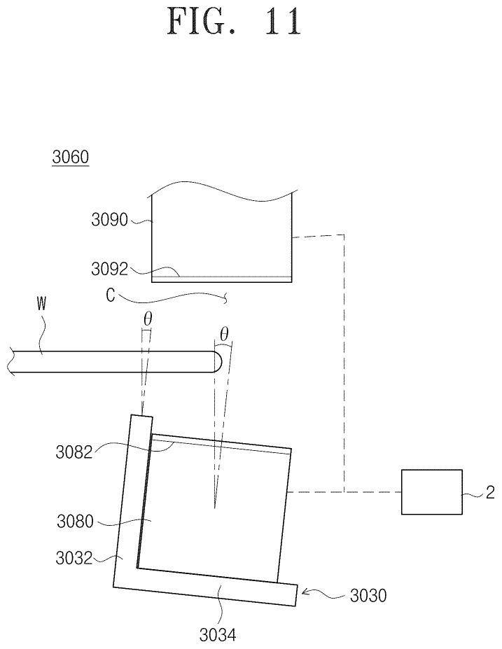

FIGS. 10 and 11 are diagrams schematically illustrating methods of setting an angle of the detector of FIG. 9, respectively.

According to the exemplary embodiment, as illustrated in FIG. 10, the detector 3060 may further include a detector 4012. The detector 4012 detects the inclination angle θ of the light emitting sensor 3080. The detector 4012 is installed on the sidewall 3032 of the holder 3030. The detector 4012 is located between the sidewall 3032 of the holder 3030 and the light emitting sensor 3080. In this case, the light emitting sensor 3080 is inclined by the predetermined angle θ with respect to the virtual straight line perpendicular to the substrate W, and the holder 3030 is not inclined. That is, the light emitting sensor 3080 is installed in a state of being inclined with respect to the holder 3030.

According to another exemplary embodiment, the holder 3030 supporting the light emitting sensor 3080 may be inclined by the angle θ together with the light emitting sensor 3080 as illustrated in FIG. 11. That is, the sidewall 3032 of the holder 3030 and the light emitted from the light emitting sensor 3080 are inclined by the same angle θ. In this case, the separate detector 4012 may not be provided.

According to an example, each detector 3060 detects the position of the end portion of the substrate W placed on the hand 3040 when the hand 3040 is in the retracted position. The position of the end portion of the substrate W detected by each detector 3060 is transmitted to the controller 2. The controller 2 determines the degree to which the substrate W placed on the hand 3040 deviates from the correct position of the substrate W on the hand 3040 based on the position value of the end portion of the substrate W transmitted from the detector 3060.

Based on the above determination, the controller 2 may correct the transfer position of the transfer robot 900 so that the substrate W is placed at the correct position of a substrate transfer region B when the hand 3040 transfers the substrate W to the substrate transfer region B of FIG. 8.

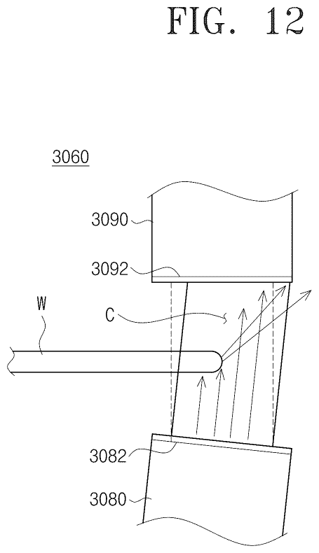

FIG. 12 is a diagram schematically illustrating light emitted by the detector of the transfer unit of FIG. 9.

Referring to FIG. 12, the light emitting sensor 3080 is provided to be inclined downward with respect to the substrate W in a direction in which the light emitting surface 3082 faces outward in the radial direction of the substrate W. Accordingly, light is emitted in a direction from the inside to the outside in the radial direction of the substrate W. In general, the end portion of the substrate W is rounded, and the upper and lower surfaces have shapes parallel to each other. Compared to the case where the light emitting surface 3082 is provided to be parallel to the light receiving surface 3092 to emit light, the light hitting the end portion of the substrate W is diffusely reflected, and a large amount of the diffusely reflected light is received by the light receiving sensor 3090. However, when the light emitting surface 3082 is provided to emit light obliquely to the substrate W as in the present invention, it is possible to minimize the light diffusely reflected from the end portion of the substrate W from being received by the light receiving sensor 3090. Accordingly, it is possible to prevent the light receiving sensor 3090 from incorrectly detecting the position of the end portion of the substrate W by the light that is diffusely reflected.

In the above exemplary embodiment, the present invention has been described based on the case where the detector is provided to the transfer unit 3000 for transferring the substrate W in the substrate processing apparatus performing the application and development processes as an example. However, the transfer unit 3000, in which the above-described detector 3060 is are installed, may be provided to the substrate processing apparatus performing processes other than those performing the application and development processes. For example, the transfer unit 3000 in which the detector 3060 is installed may be a transfer unit provided to an apparatus that performs a process of cleaning the substrate W.

The above-described technical idea of the present invention may also be applied to the substrate support unit in which the detector 3060 for detecting the position of the substrate W is installed. As in the above-described example, the hand 3040 may correspond to the support unit in the transfer unit 3000.

In the above exemplary embodiment, the present invention has been described based on the case where the light emitting sensor 3080 is installed at a lower position than the substrate W, and the light receiving sensor 3090 is installed at a higher position than the substrate to face each other as an example. However, this is illustrative and the present invention is not limited thereto. Unlike the above exemplary embodiment, the light emitting sensor 3080 may be installed at a higher position than the substrate W, and the light receiving sensor 3090 may be installed at a lower position than the substrate W.

The support unit 4000 including the detector 3060 of the present invention may be provided to the process chamber 5000 that performs a predetermined process on the substrate W. For example, the process chamber 5000 may be an applying chamber for performing an applying process for applying a resist to the substrate W. The process chamber 5000 has a support unit 5010, a resist supply nozzle 5020, and an edge removing liquid supply nozzle 5030. The support unit 5010 has a rotatable support 5012 and a detector 3060. In the process chamber 5000, the photoresist is supplied onto the substrate W placed on the support 5012, and then an edge removing liquid is supplied. When the substrate W is placed on the support 5012 by the transfer unit 3000, the position of the substrate W placed on the support 5012 is detected by the detector 3060. When the position of the detected substrate W on the support 5012 is different from the correct position of the substrate W on the support 5012, the edge removing liquid may be supplied after relatively moving the position of the support 5012 or the edge removing liquid supply nozzle 5030.

The support unit 6010 including the detector 3060 of the present invention may be provided to the process chamber 6000 that performs an edge exposure process. The process chamber 6000 includes a support unit 6010 and an edge exposure unit 6020. The support unit 6010 has a rotatable support 6012 and a detector 3060. When the substrate W is placed on the support 6012 by the transfer unit 3000, the position of the substrate W placed on the support 6012 is detected by the detector 3060. While the detection is performed, the support 6012 may be rotated. When the detected position of the substrate W on the support 6012 is different from the correct position of the substrate W on the support 6012, the substrate W may be edge-exposed while rotating the substrate W.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A transfer unit for transferring a substrate, the transfer unit comprising:
a hand on which a substrate is placed; and
a detector for detecting the degree to which the substrate placed on the hand is out of a correct position of the substrate on the hand,
wherein the detector includes:
a light emitting sensor located on one side between an upper side and a lower side of the substrate placed at the correct position on the hand to emit light; and
a light receiving sensor located on the other side between the upper side and the lower side of the substrate placed at the correct position on the hand to receive the light emitted by the light emitting sensor, and
the light emitting sensor is installed to emit light obliquely to the substrate in a direction toward an outside of a radial direction of the substrate placed at the correct position on the hand.

2. The transfer unit of claim 1, wherein a light emitting surface of the light emitting sensor is provided to be inclined with respect to the substrate placed at the correct position on the hand.

3. The transfer unit of claim 1, wherein a light receiving surface of the light receiving sensor is provided parallel to the substrate placed at the correct position on the hand.

4. The transfer unit of claim 3, wherein a light emitting surface of the light emitting sensor is provided to be inclined with respect to a light receiving surface of the light receiving sensor.

5. The transfer unit of claim 1, wherein the light emitting sensor is placed below the substrate placed at the correct position on the hand, and the light receiving sensor is placed above the substrate placed at the correct position on the hand.

6. The transfer unit of claim 1, wherein the detector is installed at a position for detecting an end portion of the substrate placed at the correct position on the hand.

7. The transfer unit of claim 1, further comprising:
a controller,
wherein the controller detects a position of the substrate based on the amount of light received by the light receiving sensor.

8. The transfer unit of claim 1, further comprising:
a base plate,
wherein the hand is provided to move forward and backward between a forward position and a retracted position with respect to the base plate, and
the detector is fixedly installed in the base plate.

9. The transfer unit of claim 8, wherein the detector is provided to detect the position of the substrate placed on the hand when the hand is located at the retracted position with respect to the base plate.

10. The transfer unit of claim 1, wherein the detector is provided in plural,
the plurality of detectors is provided to detect different regions of an end portion of the substrate placed on the hand,
the transfer unit further comprises a controller, and
based on a position of the end portion of the substrate detected by the plurality of detectors, the controller determines the degree to which the position of the substrate placed on the hand is out of the correct position of the substrate on the hand.

11. The transfer unit of claim 1, wherein an angle (θ) at which light is emitted obliquely is 1 degree to 6 degrees.

12. A support unit for supporting a substrate, the support unit comprising:
a support for supporting a substrate; and
a detector for detecting the degree to which the substrate placed on the support is out of a correct position of the substrate on the support,
wherein the detector includes:
a light emitting sensor located on one side between an upper side and a lower side of the substrate placed at the correct position on the support to emit light; and
a light receiving sensor located on the other side between the upper side and the lower side of the substrate placed at the correct position on the support to receive the light emitted by the light emitting sensor, and
the light emitting sensor is installed to emit light obliquely to the substrate in a direction toward an outside of a radial direction of the substrate placed at the correct position on the support.

13. The support unit of claim 12, wherein a light emitting surface of the light emitting sensor is provided to be inclined with respect to the substrate placed on the support.

14. The support unit of claim 12, wherein a light receiving surface of the light receiving sensor is provided to be parallel to the substrate placed on the support.

15. The support unit of claim 12, wherein a light emitting surface of the light emitting sensor is provided to be inclined with respect to a light receiving surface of the light receiving sensor.

16. The support unit of claim 12, wherein the support is a hand on which the substrate is placed in a transfer robot that transfers the substrate.

17. The support unit of claim 12, wherein the detector is provided in plural, and
the plurality of detectors is provided to detect different regions of the substrate placed on the support.

18. The support unit of claim 17, further comprising:
a controller,
wherein each of the detectors detects a position of an end portion of the substrate placed on the support, and
based on the position of the end portion of the substrate detected by the plurality of detectors, the controller determines the degree to which the position of the substrate placed on the support is out of a correct position of the substrate on the support.

19. A transfer unit for transferring a substrate, the transfer unit comprising:
a base plate;
a hand which is provided to be movable forward and backward with respect to the base plate, and on which the substrate is placed; and
a plurality of detectors for detecting the degree to which the substrate placed on the hand is out of a correct position of the substrate on the hand when the hand is located at a retracted position with respect to the base plate,
wherein the plurality of detectors is installed on the base plate to detect different regions of the substrate placed on the hand,
each of the detectors includes:
a light emitting sensor located on one side of an upper side and a lower side of the substrate placed at the correct position on the hand to emit light; and
a light receiving sensor located on the other side between the upper side and the lower side of the substrate placed at the correct position on the hand to receive the light emitted by the light emitting sensor, and
the light emitting sensor is installed to emit light obliquely to the substrate in a direction toward an outside of a radial direction of the substrate placed at the correct position on the hand.

20. The transfer unit of claim 19, wherein a light emitting surface of the light emitting sensor is provided to be inclined with respect to a light receiving surface of the light receiving sensor.
